(19) United States
(12) Patent Application Publication
(10) Pub. No.: US 2011/0135426 A1
(43) Pub. Date: Jun. 9, 2011

(54) VACUUM TRANSFER APPARATUS

(75) Inventors: Tamaya Shunsuke, Kawasaki-shi (JP); Itou Wataru, Kawasai-shi (JP)

(73) Assignee: CANON ANELVA CORPORATION, Kanagawa (JP)

(21) Appl. No.: 12/863,064

(22) PCT Filed: Jan. 27, 2009
(86) PCT No.: PCT/JP2009/051237

§ 371 Date: Feb. 14, 2011

(30) Foreign Application Priority Data
Jan. 31, 2008 (JP) 2008-020915

(51) Int. Cl. H01L 21/677; B25J 9/00

(52) U.S. Cl. 414/217; 414/805

(57) ABSTRACT

Disclosed is a vacuum transfer apparatus, which can increase a transfer amount in a vertical direction of a transferred object and can reduce a volume required for placement of the vacuum transfer apparatus, whereby contributing to the size reduction of the vacuum transfer apparatus.

The vacuum transfer apparatus includes a horizontal transfer mechanism 111 for transferring a substrate 100 in a horizontal direction, a vertical transfer mechanism 112 for transferring the substrate 100 in a vertical direction, a vacuum vessel 101 including the horizontal transfer mechanism 111 and the vertical transfer mechanism 112, a horizontal driving part 113 having X and Y axis direction driving shafts 107a and 107b disposed in the vacuum vessel 101 and driving the horizontal transfer mechanism 111 by means of the X and Y axis direction driving shafts 107a and 107b, and a vertical driving part 114 having Z axis direction driving shafts 108a and 108b disposed in the vacuum vessel 101 and driving the vertical transfer mechanism 112 by means of the Z axis direction driving shafts 108a and 108b.

### TECHNICAL FIELD

This invention relates to a vacuum transfer apparatus for transferring a transferred object, such as a substrate, in a vacuum chamber in three axis directions.

### BACKGROUND ART

For example, a semiconductor manufacturing apparatus and a flat panel display manufacturing apparatus use a vacuum transfer apparatus serving as transfer means for transferring a substrate in a vacuum chamber constituted of, for example, a vacuum vessel,

As a representative configuration of a substrate transfer apparatus for transferring a substrate in a vacuum chamber, there has been known a configuration disclosed in FIG. 10 of Patent Document 1.

In the Patent Document 1, a driving system used in a power and control is disposed outside a vacuum vessel and is connected through a vacuum flange. The vacuum vessel contains only an arm part for actually holding and transferring a substrate, and the driving system and a transferring system are separated by the vacuum vessel.

Basically, a substrate is transferred in a horizontal direction based on the extending and shrinking operations of an arm part provided inside a vacuum vessel. A rotation operation is transmitted as a driving force from a driving system provided outside the vacuum vessel to the arm part in the vacuum vessel by a rotational drive mechanism generating a rotational driving force, and the arm part is extended and shrunk, whereby the substrate can be transferred in the horizontal direction.

The substrate can be transferred in the vertical direction (lifting direction) in the vacuum vessel in response to the level of extending and shrinking (stroke level) of a metallic bellows provided in a connecting part of the driving system disposed outside the vacuum vessel. Thus, when the transfer amount in the vertical direction is increased, an extendable and shrinkable length of the metallic bellows connected outside the vacuum vessel should be increased.

In the transfer of the substrate by the vacuum transfer apparatus, in order to realize high efficiency in a semiconductor manufacturing apparatus and a flat panel display manufacturing apparatus, recently, the transfer amount in the vertical direction of a substrate is required to be more secured than other transfer directions. Further, a substrate is required to be transferred in a vacuum transfer apparatus under a cleaner environment.

However, in the constitution of the conventional vacuum transfer apparatus, the increase of the transfer amount in the vertical direction is accompanied by the increase of the stroke level of the metallic bellows disposed outside the vacuum vessel, and the increasing amount of the length of the metallic bellows becomes two to three times the transfer amount Thus, since a volume occupied by the metallic bellows outside the vacuum vessel increases, a volume required for placement of the vacuum transfer apparatus tends to significantly increase with the increase of the transfer amount in the vertical direction. Further, since the rotation operation used in the transfer in the horizontal direction (X and Y axis directions) depends on the transmission of the rotation operation through a long rotation shaft, it is accompanied by reduction of the rotating torque and increasing of the diameter of the rotation shaft.

In order to prevent the increasing of the length of the metallic bellows outside the vacuum vessel, a constitution for improving a vacuum seal structure of a part of a drive system is disclosed in FIG. 1 of Patent Document 2, In the constitution of the Patent Document 2, a mechanical seal is adopted in the seal structure instead of a magnetic fluid seal, and a mechanism in which a sealed portion floats and moves in response to the lifting operation of a rotation shaft. According to this constitution, although the length of the metallic bellows itself is reduced, the volume required for the vertical motion is not necessarily reduced.

Patent Document 1 Japanese Patent Application Laid-Open No. 9-131680 (FIG. 10)

Patent Document 2 Japanese Patent Application Laid-Open No 2005-161409 (FIG. 1)

### DISCLOSURE OF THE INVENTION

### Problems to Be Solved by the Invention

In the above related art, in order to increase the transfer amount in the vertical direction in the lifting operation, it is essential to secure the volume for the vertical motion outside the vacuum vessel. The constitution disclosed in the Patent Document 2 can avoid the increase in size of the metallic bellows disposed outside the vacuum vessel. On the other hand, in the constitutions disclosed in the Patent Document 1 and 2, the driving shaft with a length realizing the necessary transfer amount in the vertical direction is disposed outside the vacuum vessel, whereby there are such disadvantages that the vacuum vessel is increased in size, and the volume required for placement of the vacuum transfer apparatus cannot be reduced.

An object of this invention is to provide a vacuum transfer apparatus which can solve the above problems and can increase the transfer amount in the vertical direction of a transferred object, and, at the same time, can reduce a volume required for placement of the vacuum transfer apparatus, whereby the entire size of the vacuum transfer apparatus can be reduced.

### Means for Resolving the Problems

In order to achieve the above object, the vacuum transfer apparatus according to this invention includes two-dimensional transfer means for transferring a transferred object in a two-dimensional direction, support means which itself does not move translationally and supports the two-dimensional transfer means, and a vacuum chamber including the two-dimensional means and the support means. The vacuum transfer apparatus is characterized in that the support means is constituted so that the two-dimensional transfer means can be moved in a direction vertical to a plane formed by the tow-dimensional transfer means.

### Effects of the Invention

According to this invention, the two-dimensional transfer means and the support means are disposed inside the vacuum chamber, whereby the transfer amount (lifting amount) of a transferred object in a direction vertical to the transfer direction, by the two-dimensional transfer means is increased, and, at the same time, a volume required for placement of the vacuum transfer apparatus can be reduced. Therefore, this invention can reduce the entire size of the vacuum transfer apparatus.

### BRIEF DESCRIPTION OF THE DRAWINGS

FIG. 1 is a perspective view showing a schematic configuration of a vacuum transfer robot of the present embodiment;

FIG. 2 is a cross-sectional view showing a horizontal transfer mechanism and a horizontal driving part of the vacuum transfer robot;

FIG. 3 is a cross-sectional view showing a vertical transfer mechanism and a vertical driving part of the vacuum transfer robot;

FIG. 4 is a schematic view for explaining a connection structure between a vacuum vessel and a base;

FIG. 5 is a view showing a use example of a vacuum transfer apparatus of this invention;

FIG. 6 is a view showing another use example of the vacuum transfer apparatus of this invention;

FIG. 7 is a schematic diagram of a cross-sectional structure of an organic EL display manufactured by using a processing apparatus of this invention; and

FIG. 8 is a perspective view showing a structure of an electron emission element display apparatus manufactured by using the processing apparatus of this invention.

### DESCRIPTION OF THE NUMERALS

100 Substrate
101 Vacuum vessel
103 Hand
104 Second arm
105 First arm
106 Base
107a, 107b X and Y axis direction driving shaft
108a, 108b Z axis direction driving shaft
111 Horizontal transfer mechanism
112 Vertical transfer mechanism
113 Horizontal driving part
114 Vertical driving part
201 Rotating generator
220 Rotation shaft
221 Rotation shaft
223 Rotation shaft
301 Rotating generator
401 Connection port
402 Valve body
411 Vacuum outlet
412 Valve body

### THE BEST MODE FOR CARRYING OUT THE INVENTION

Hereinafter, an embodiment of this invention will be described with reference to the drawings.

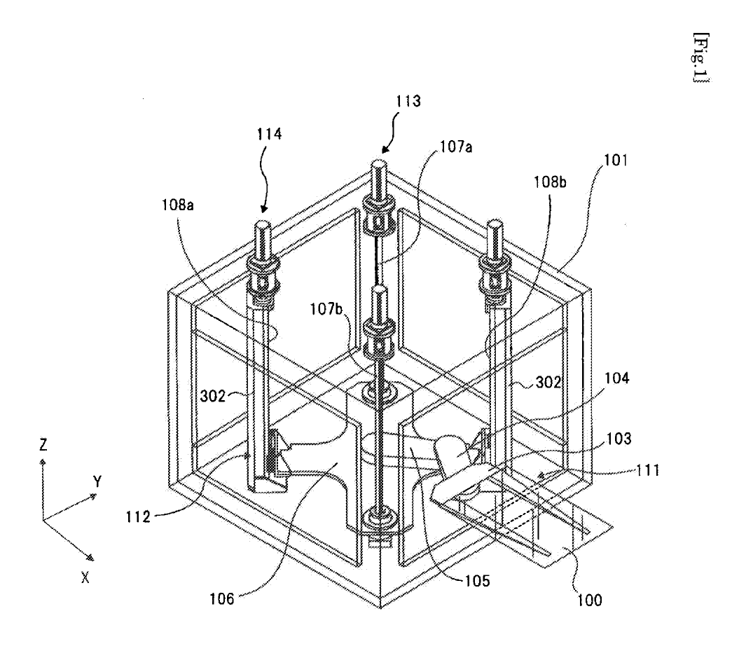

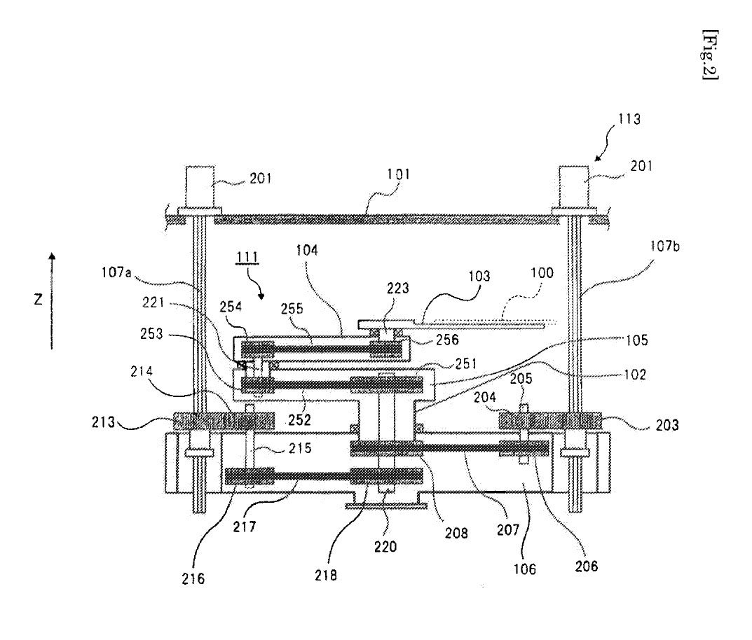

FIG. 1 is a perspective view showing a schematic constitution of a vacuum transfer robot of the present embodiment as a vacuum transfer apparatus according to this invention. FIG. 2 is a cross-sectional view showing a schematic constitution of a horizontal transfer mechanism and a horizontal driving part of the vacuum transfer robot of this embodiment. In this embodiment, a two-dimensional direction is a horizontal plane direction, and a direction vertical thereto is a vertical direction.

As shown in FIG. 1, the vacuum transfer robot of this embodiment is used for transferring a substrate 100 in three axis directions. The substrate 100 is a transferred object mounted with a device structure for a semiconductor and various displays. The vacuum transfer robot includes a horizontal transfer mechanism 111 which is two-dimensional transfer means for transferring the substrate 100 in the horizontal (X and Y axis) directions that is the two-dimensional direction and a vertical transfer mechanism 112 which is support means for transferring the horizontal transfer mechanism 111 in the vertical direction (Z axis direction).

The vacuum transfer robot includes a vacuum vessel 101 which is a vacuum chamber including the horizontal transfer mechanism 111 and the vertical transfer mechanism 112. The vacuum transfer robot further includes a horizontal driving part 113 for driving the horizontal transfer mechanism 111 and a vertical driving part 114 which is driving means for driving the vertical transfer mechanism 112.

The horizontal transfer mechanism 111, as shown in FIGS, 1 and 2, has a first arm 105, a second arm 104, and a hand 103 which are arm members supporting the substrate 100. The horizontal transfer mechanism 111 further has a rotating mechanism and case members for accommodating the rotating mechanism. The rotating mechanism includes rotation shafts 220, 221, and 223 rotatably connecting and supporting the first arm 105, the second arm 104, and the hand 103.

One end of the first arm 105 is supported on a base 106 through the rotation shaft 220. The other end of the first arm 105 supports one end of the second arm 104 through the rotation shaft 221. Further, the other end of the second arm 104 supports the hand 103, on which the substrate 100 is placed, through the rotation shaft 223. The substrate 100 placed on the hand 103 is transferred to an arbitrary position in the horizontal direction by the horizontal transfer mechanism 111, and, at the same time, transferred at an arbitrary height in the vertical direction by the vertical transfer mechanism 112.

The vertical transfer mechanism 112 of the vacuum transfer robot has the base 106, which is a base member supporting the horizontal transfer mechanism 111, and a moving mechanism including a supporting member 302 for supporting the base 106 movably in the vertical direction.

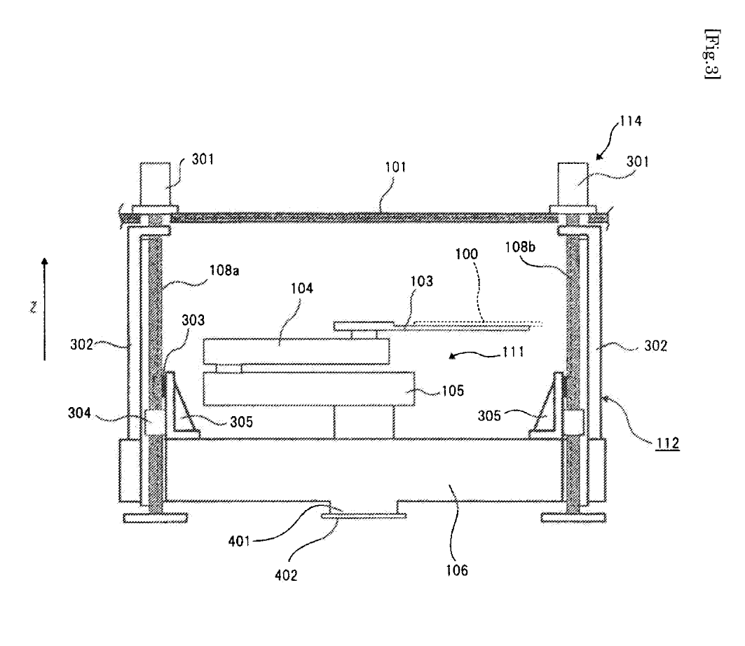

The horizontal driving part 113 of the vacuum transfer robot has a pair of X and Y axis direction driving shafts 107a and 107b, which are driving shafts for the horizontal direction driving the horizontal transfer mechanism 111, and a rotating generator 201 which rotates and drives the driving shafts 107a and 107b. The vertical driving part 114 itself does not move translationally, in other words, does not move in the two-dimensional direction, and is provided and fixed to the vacuum vessel 101 in order to prevent the movement of the vertical driving part 114. The vertical driving part 114, as shown in FIG. 3, has a pair of Z axis direction driving shafts 108a and 108b (a pair of conversion means), which are driving shafts for the vertical direction driving the vertical transfer mechanism 112, and a rotating generator 301 which rotates and drives the driving shafts 108a and 108b.

The rotating generators 201 and 301 have a constitution so that a servo motor and a harmonic drive, for example, are used. A control part (not shown) of the vacuum transfer robot controls the drive of the rotating generator 301 based on a control program, whereby the driving shafts 108a and 108b disposed to face each other are synchronized to be driven to rotate.

As shown in FIG. 1, the vacuum vessel 101 includes the pair of X and Y axis direction driving shafts 107a and 107b and the pair of Z axis direction driving shafts 108a and 108b. The pair of X and Y axis direction driving shafts 107a and 107b and the pair of Z axis direction driving shafts 108a and 108b are disposed to face a center axis, which is a center axis of the plane formed by the horizontal transfer mechanism 111 and passes through the center of the base 106. Namely, the pair of X and Y axis direction driving shafts 107a and 107b and the pair of Z axis direction driving shafts 108a and 108b are constituted so as to be disposed on the respective diagonal lines of the base 106. The X and Y axis direction driving shafts 107a and 107b and the Z axis direction driving shafts 108a and 108b respectively include at their both ends the rotating generators 201 and 301, provided outside the vacuum vessel 101, through the wall of the upper surface of the vacuum vessel 101. The horizontal driving part 113 and the vertical driving part 114 can provide arbitrary rotation to the driving shafts 107a, 107b, 108a, and 108b by means of the rotating generators 201 and 301, The pair of X and Y axis direction driving shafts 107a and 107b and the pair of Z axis direction driving shafts 108a and 108b are mechanically connected to the base 106 disposed with the horizontal transfer mechanism 111. The pair of X and Y axis direction driving shafts 107a and 107b and the pair of Z axis direction driving shafts 108a and 108b are accommodated in the vacuum vessel 101 and are always exposed in a vacuum atmosphere The Z axis direction driving shafts 108a and 108b are not necessarily disposed to face each other.

The vacuum transfer robot further includes an evacuation part (not shown) including an evacuation pump for evacuating the inside of the base 106 and the inside of the case members of the horizontal transfer mechanism 111.

As shown in FIG. 2, the rotating generator 201 is provided outside the vacuum vessel 101 and connected to the X and Y axis direction driving shafts 107a and 107b through a vacuum rotation introducing mechanism (not shown). A rotational force is introduced inside the vacuum vessel 101 through, for example, a magnetic fluid seal.

Regardless of this invention, a vacuum transfer robot is generally constituted so that a transferred object can be transferred to an arbitrary position in the horizontal direction. A constitution for transferring the substrate 100 to an arbitrary position in the horizontal direction by means of the horizontal transfer mechanism 111 in the vacuum transfer robot of the present embodiment is described as follows.

The horizontal transfer mechanism 111 transfers the substrate 100 in the horizontal direction by extending or shrinking the first arm 105, the second arm 104, and the hand 103. The constitution shown in FIG. 2 realizes an example of a mechanism for extending or shrinking them.

As shown in FIG. 2, a rotational driving force generated by the rotating generator 201 is transmitted to a gear 213 by a ball spline as the X and Y axis direction driving shaft 107a. The ball spline is constituted so that a large number of steel balls are interposed between a spline shaft and a sleeve. In the ball spline structure, while steel balls are circulated, movement can be performed with a rolling pair irrespective of the length of stroke. Therefore, the ball spline can transmit the rotational driving force as a rotational motion, and, at the same time, can be easily driven as a smooth linear motion with respect to the operation in its axis direction.

The gear 213 meshes with and is connected to a gear 214 in the vacuum vessel 101. When the rotational driving force is transmitted from the gear 213 to the gear 214, another gear may be provided between the gears 213 and 214. If necessary, a lubricant for vacuum is applied or coated to between the gears 213 and 214, whereby a smooth meshed state can be secured.

The rotational driving force transmitted to the gear 214 rotates and drives a pulley 216, disposed in the base 106, through a rotation shaft 215. The rotational driving force in the pulley 216 is transmitted to a pulley 218 through a timing belt 217 to rotate and drive the pulley 218. The pulley 218 is fixed to a rotation shaft 220, and the rotational driving force is transmitted to a pulley 251, disposed in the first arm 105 and fixed to the rotation shaft 220, through the rotation shaft 220ᵣ The rotational driving force in the pulley 251 is transmitted to a pulley 253, similarly disposed in the first arm 105, through a timing belt 252.

The pulley 253 is connected to the second arm 104 through a rotation shaft 221 and can control the rotation operation of the second arm 104 by the rotational drive of the pulley 253. At the same time, the rotational driving force is transmitted through the rotation shaft 221 while the second arm 104 is rotated, whereby a pulley 254 can be rotated and driven. Likewise, the rotational driving force transmitted to the pulley 254 is transmitted to a pulley 256 through a timing belt 255 to rotate and drive the pulley 256. The pulley 256 is connected to the hand 103 through a rotation shaft 223, and the pulley 256 is rotated and driven to thereby rotate the hand 103 through the rotation shaft 223, whereby the hand 103 can be moved to a desired position.

Meanwhile, the rotational driving force generated by the rotating generator 201 is transmitted to a gear 203 through the ball spline as the X and Y axis direction driving shaft 107b. The gear 203 meshes with and is connected to a gear 204 in the vacuum vessel 101. When the rotational driving force is transmitted from the gear 203 to the gear 204, another gear may be provided between the gears 203 and 204. If necessary, a lubricant for vacuum is applied or coated to between the gears 213 and 214, whereby a smooth meshed state can be secured.

The rotational driving force transmitted to the gear 204 rotates and drives a pulley 206, disposed in the base 106, through a rotation shaft 205. The rotational driving force transmitted to the gear 206 is transmitted to a pulley 208 through a timing belt 207 to rotate and drive the pulley 208. The pulley 208 is fixed to an outer wall 102 of a cylinder portion projecting toward the first arm 105, and the pulley 208 has a hollow structure for passing the rotation shaft 220 therethrough. The rotational drive of the pulley 208 rotates the first arm 105 at an arbitrary angle to allow the first arm 105 to move to a desired position.

As described above, the rotational driving force generated by the rotating generator 201 is transmitted through each rotational shaft, gear, timing belt, and pulley, whereby the first arm 105, the second arm 104, and the hand 103 can be arbitrarily rotated and can be horizontally moved. The combination of the motions of those members can realize the transfer of the substrate 100 to an arbitrary position in the horizontal direction, that is required for a general vacuum transfer robot. Namely, the rotational driving force from the ball spline is transmitted to the arms 105 and 104 through each gear, timing belt, and pulley to be converted into continuous extending and shrinking motions (horizontal motion) of each of the arms 105 and 104, whereby the substrate 100 is transferred in the horizontal direction.

The vacuum transfer robot of the present embodiment includes the horizontal transfer mechanism 111 and the horizontal driving part 113 shown in FIG. 2, whereby the X and Y axis direction driving shafts 107a and 107b required for the rotation operation of the horizontal transfer mechanism 111 can be disposed inside the vacuum vessel 101. Therefore, a volume required for placement of the vacuum transfer robot can be reduced.

FIG. 3 is a cross-sectional view showing a schematic configuration of a vertical transfer mechanism and a vertical driving part of the vacuum transfer robot of the present embodiment. As shown in FIG. 3, the rotating generator 301 is disposed outside the vacuum vessel 101 so as to face the center of the base 106. The rotating generator 301 is connected to the Z axis direction driving shafts 108a and 108b, disposed to face the center of the base 106, using a vacuum rotation introducing mechanism. The Z axis direction driving shafts 108a and 108b are not necessarily disposed to face each other.

In addition to the realization of the above-described horizontal transfer, the vacuum transfer robot is generally required to transfer a transferred object in the vertical (Z axis) direction. In the present embodiment, the Z axis direction driving shafts 108a and 108b are operated to rotate, and, thus, to transfer the base 106 in the vertical direction, whereby the transferred object can be transferred in the Z axis direction. Further, in general, in order to increase the transfer amount (lifting amount) in the Z axis direction, a large placement volume in the Z axis direction, that is, a space for the movement of the Z axis direction driving shaft is required outside the bottom surface of the vacuum vessel. In the present embodiment, as shown in FIG. 3, the Z axis direction driving shafts 108a and 108b are disposed inside the vacuum vessel 101, whereby the Z axis direction driving shafts 108a and 108b can have a large length without increasing the volume required for the placement of the Z axis direction driving shaft.

When ball screws which are rotation shafts are used as the Z axis direction driving shafts 108a and 108b, the rotational driving force generated by the rotating generator 301 is converted into a linear driving force in the Z axis direction. A bracket 305 is connected to the ball screws through a nut 304 which serves as a screw part formed around the rotation shaft and is disposed so as to correspond to a spiral groove.

Thus, the base 106 can be lifted upward or downward through the brackets 305 by the linear motion of the nuts 304 accompanying the rotation of the ball screws. Linear guides 303 for supporting the linear movement of the ball screws are disposed in parallel to the ball screws, whereby a reliability of the linear motion of the ball screws and the base 106 can be ensured.

In addition, the rotating generators 301 having the same structure are symmetrically disposed with respect to the center of the base 106. These rotating generators 301 are synchronized to be driven and controlled, whereby the horizontal transfer mechanism 111 provided on the base 106 can be moved in the vertical direction with the base 106 kept in a state parallel to the horizontal direction. At that time, the ball spline as the X and Y axis direction driving shaft 107 shown in FIG. 2 can move the base 106 smoothly in the vertical direction without preventing the lifting motion of the base 106.

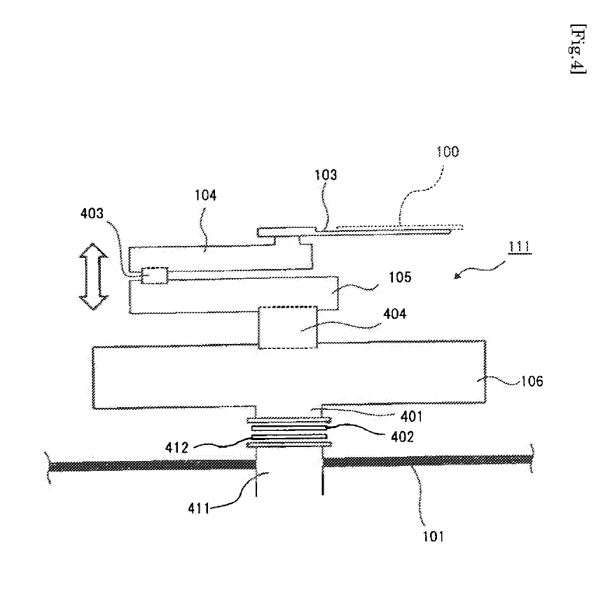

FIG. 4 is a schematic diagram showing a constitution of a horizontal transfer mechanism and shows an example of constitution that can perform vacuum evacuation of the inside of each case member constituting the horizontal transfer mechanism 111.

As shown in FIG. 4, the horizontal transfer mechanism 111 disposed in the vacuum vessel 101 constitutes an enclosed structure in which various mechanism components are accommodated in the case members. The first and second arms 104 and 105 are rotatably connected through tubular shaft members 403 and 404 constituting the individual case members, and the rotation shafts 221 and 220 are respectively inserted into the shaft members 403 and 404. The shaft members 403 and 404 have a hollow structure, and the atmosphere is communicated in the horizontal transfer mechanism 111. The shaft members 403 and 404 themselves are tubular members formed of metal, and at least one of them is rotatably connected to the adjacent member with, for example, a magnetic seal. Such a constitution is used in FIG. 10 of the Patent Document 1.

In the present embodiment, the atmosphere in the horizontal transfer mechanism 111 and the atmosphere in the base 106 communicate with each other through the shaft member 404 constituting the case member. The vacuum vessel 101 and the base 106 respectively have a connection port 401 and a vacuum outlet 411 which are connecting parts detachably connected to each other. The connection port 401 in the lower portion of the base 106 has a valve body 402. The vacuum outlet 411 is provided in the bottom surface portion of the vacuum vessel 101 so as to face the connection port 401 of the base 106 and has a valve body 412. The base 106 communicates with the vacuum outlet 411 through the connection port 401.

In the present embodiment, as with the constitution of the Patent Document 1, the connection port 401 of the base 106 and the vacuum outlet 411 of the vacuum vessel 101 are not in a state of being always connected to each other, but they are connected at proper timing. When the connection port 401 and the vacuum outlet 411 are connected to each other, the valve body 402 of on the base 106 side and the valve body 412 on the vacuum vessel 101 side are opened, whereby vacuum evacuation is performed by an evacuation part.

The pressure of the horizontal transfer mechanism 111 disposed in the vacuum vessel 101 and having an enclosed structure is gradually increased by gas emitted from a mechanism component such as a bearing structure in the horizontal transfer mechanism 111. Thus, when it is considered to prevent contamination of the vacuum atmosphere in the vacuum vessel 101, the vacuum evacuation of the case members of the horizontal transfer mechanism 111 should be performed at proper timing. At the same time, since a relatively long distance transfer is performed in the vertical direction (Z axis direction), the case members of the horizontal transfer mechanism 111 cannot maintain a state that the connection port 401 and the vacuum outlet 411 are always connected so that the inside of the case members can be always evacuated into vacuum.

Therefore, in the present embodiment, the valve body 402 is provided in the connection port 401 of the base 106, of which the inside communicates with the case members, and the pressure inside the case members, which constitutes the enclosed structure of the horizontal transfer mechanism 111, can be maintained. When the connection port 401 and the vacuum outlet 411 are connected at proper timing, a forcible or passive external force is added, and the valve bodies 402 and 412 are opened and operated, whereby the inside of the case members in the horizontal transfer mechanism 111 can be evacuated into vacuum. Meanwhile, the valve body 402 is closed during the movement in the vertical direction in the vacuum vessel 101, whereby the inside of the horizontal transfer mechanism 111 can be maintained at not more than a predetermined pressure. Namely, if necessary, the inside of the base 106 and the inside of the case members of the horizontal transfer mechanism 111 can be maintained in a proper decompressed environment.

As described above, according to the present embodiment, the X and Y axis direction driving shafts 107a and 107b driving the horizontal transfer mechanism 111 and the Z axis direction driving shafts 108a and 108b driving the vertical transfer mechanism 112 are disposed inside the vacuum vessel 101. According to this constitution, the transfer amount (lifting amount) in the vertical direction of the substrate 100 is increased, and, at the same time, the volume required for placement of the vacuum transfer apparatus can be reduced, whereby the entire size of the vacuum transfer robot can be reduced.

Namely, instead of a conventional constitution in which a driving shaft is disposed to be exposed outside a vacuum vessel, the present embodiment uses a pair of the X and Y axis direction driving shafts 107a and 107b and a pair of the Z axis direction driving shafts 108a and 108b, which are respectively disposed inside the vacuum vessel 101 so as to face each other. The horizontal driving part 113 and the vertical driving part 114 having the X and Y axis direction driving shafts 107a and 107b and the Z axis direction driving shafts 108a and 108b can realize the transport motion in the horizontal direction and the transport motion in the vertical direction without increase of the placement volume.5 According to this constitution, the transfer amount in the vertical direction in the vacuum vessel 101 can be increased, and, at the same time, the volume required for placement of the vacuum transfer robot can be reduced. In the related art, the placement space of not less than the volume occupied by the apparatus has been required to be ensured in order to ensure a movement margin in the vertical direction; however, there is no need in this invention.

The mechanism component required for the transfer of the substrate 100 is provided independent from the vacuum vessel 101, and the horizontal transfer mechanism 111 constituting an enclosed structure in which a rotating mechanism directly connected to the X and Y axis direction driving shafts 107a and 107b is accommodated, whereby the structure in the vacuum vessel 101 is simplified. Further, according to the present embodiment, when the base 106 is transferred in the vertical direction in the vacuum vessel 101, the connection port 401 of the base 106 and the vacuum outlet 411 of the vacuum vessel 101 are airtightly closed by the valve bodies 402 and 412. The connection port 401 and the vacuum outlet 411 are connected at proper timing, and the valve bodies 402 and 412 are opened, whereby the inside of the base 106 and the inside of the case of the horizontal transfer mechanism 111 can be maintained in a proper decompressed environment. Consequently, a clean vacuum environment can be obtained.

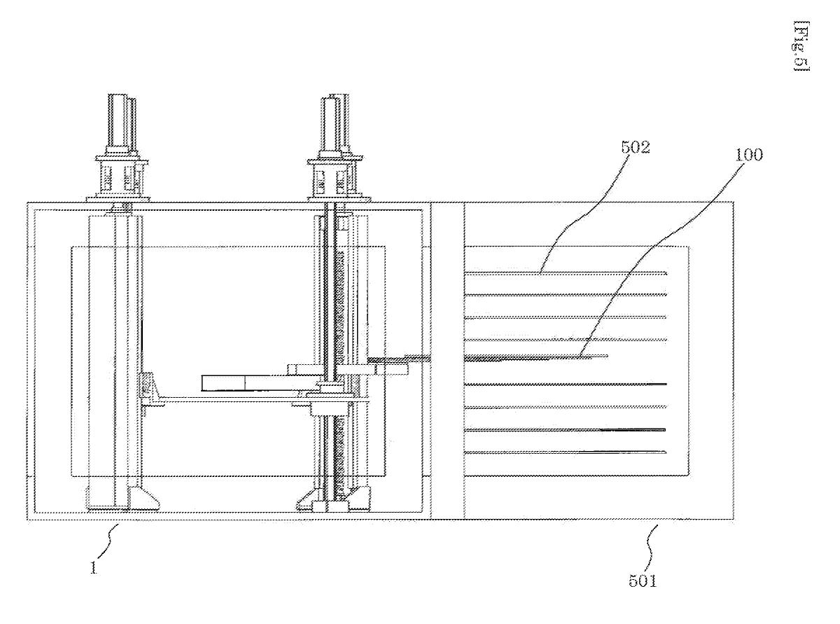

As a use example of the vacuum transfer apparatus of this invention, FIG. 5 shows an example in which a vacuum transfer apparatus 1 of this invention and a multistage vacuum sintering furnace 501 are connected to each other. In FIG. 5, a transferred object can be taken out from or put on a stage with an arbitrary height in the multistage vacuum sintering furnace 501. As described above, this invention can realize a desired function without increasing the volume occupied by the apparatus.

The usage is described. Reference numerals 1 and 501 respectively denote a vacuum transfer apparatus and a vacuum sintering furnace. A predetermined number of substrate supporting frames 502 are provided inside the vacuum sintering furnace 501, and a heater (not shown) i provided so that the substrate 100 in the vacuum sintering furnace 501 can be heated at a desired temperature.

The substrate 100 fed to the vacuum transfer apparatus 1 by any means is turned to the direction of the vacuum sintering furnace 501 by a horizontal transfer mechanism of the present apparatus. Subsequently, in order to transfer the substrate to the designated substrate supporting frame 502, the substrate is transferred to a predetermined height of the substrate supporting frame 502 by a vertical transfer mechanism. Thereafter, the horizontal transfer mechanism is operated, and the substrate 100 is transferred to the position facing the substrate supporting frame 502. An arm is moved downward to the position where the substrate 100 is placed on the substrate supporting frame 502, and thereafter, the arm is retracted by the horizontal transfer mechanism. The above operation is performed until the substrates 100 are placed on all the substrate supporting frames 502 of the vacuum sintering furnace 501. Thereafter, a gate valve (not shown) provided between the vacuum transfer apparatus 1 and the vacuum sintering furnace 501 is closed. Then the vacuum sintering furnace 501 is evacuated to a required pressure by an evacuation pump (not shown) and heated by a heater (not shown). The substrate 100 is heated for a previously set time, sintering of the substrate 100 is completed. The operation opposite to the above operation is repeated, whereby the treated substrate 100 is collected from the vacuum sintering furnace 501 into the vacuum transfer apparatus 1.

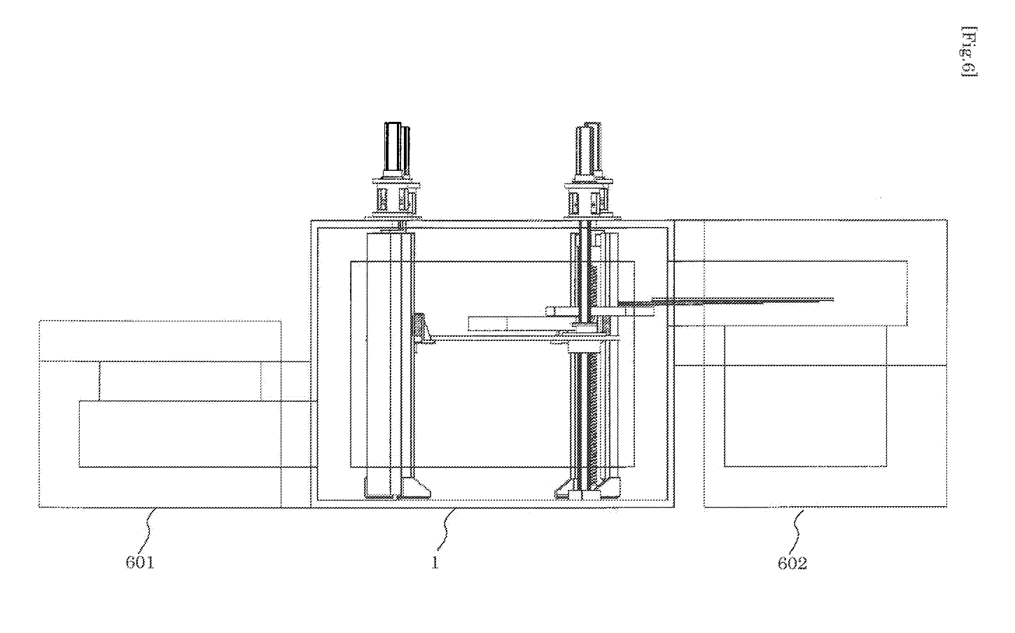

As another example, FIG. 6 shows an example in which a sputtering film-forming apparatus 601 and a deposition film forming apparatus 602 which are different in the transfer height of a transferred object are connected to the both sides of the vacuum transfer apparatus 1 of this invention. In the example of FIG. 6, a vacuum deposition film forming process requiring a transfer to a high position and a vacuum sputtering film formation process requiring a transfer to a low position can be provided in the same vacuum apparatus.

In the deposition film forming apparatus 602, a vapor deposition material in a container such as a tray is heated by an electron beam or a heater to be made into the form of gas, and, thus, to be made to travel in a substrate direction against the gravity. Once the vapor deposition material reaches the substrate, the vapor deposition material is adhered to the substrate, and a film is formed. Thus, essentially, the container containing the vapor deposition material is required to be disposed on a lower side, and the substrate on which a film is formed is required to be disposed on an upper side Further, these days, a substrate to be subjected to film-formation is increased in size, and therefore, in order to obtain an even film, a distance between the container containing the vapor deposition material and the substrate to be subjected to film-formation is required to be further increased compared with the related art. Meanwhile, unlike a vapor deposition apparatus, in a sputter apparatus, a target with a size corresponding to the size of a substrate can be used, and thus the substrate and the target are not required to be separated from each other at a distance. Accordingly, the height of the sputtering apparatus 601 is small, and the height of the deposition film forming apparatus 602 is large. When the vacuum transfer apparatus of this invention is disposed between the sputtering apparatus 601 and the deposition film forming apparatus 602, even if there is a difference in their height, the transfer operation can be smoothly performed. Consequently, the height of the sputtering apparatus 601 is not required to be unnecessarily increased just for transfer. Thus, the placement volume can be reduced. The procedure of transfer is similar to the above-described procedure, and the description is omitted.

Not only in the examples shown in FIGS, 5 and 6, but a vacuum processing apparatus can be constituted to have a plurality of vacuum chambers connected to around the vacuum transfer apparatus of this invention as the center. When the vacuum transfer apparatus of this invention is used, a transferred object can be transferred in an arbitrary horizontal plane direction and an arbitrary vertical direction, and therefore, a transfer height of the transferred object required for each vacuum chamber may be different.

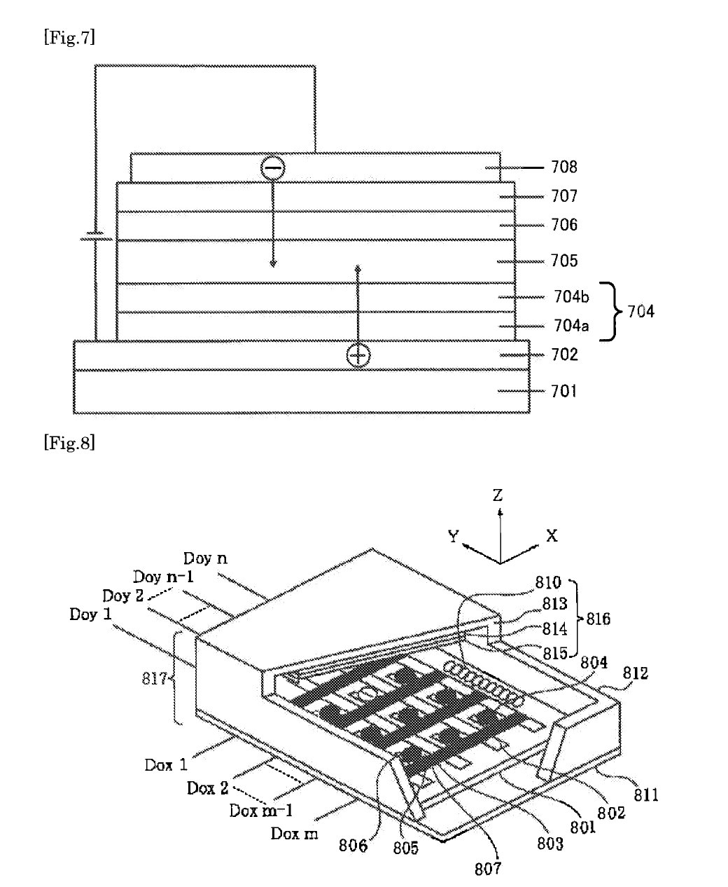

FIG. 7 is a schematic diagram of a structure of an organic fluorescent display apparatus (hereinafter referred to as an “organic EL display apparatus”) which is one of image display apparatuses particularly suitable for manufacture using the vacuum processing apparatus according to this invention.

Reference numerals 701, 702, 704, 705, 706, 707, and 708 respectively denote a glass substrate, an anode, a layer associated with a hole, an emission layer, an electron transport layer, an electron injection layer, and a cathode. The layer 704 associated with a hole is constituted of a hole injection layer 704a and a hole transport layer 704b. The anode 702 is often produced by, for example, sliver or aluminum.

In the operation, when a voltage is applied to between the anode 702 and the cathode 708, a hole is injected from the anode 702 into the hole injection layer 704a. Meanwhile, an electron is injected from the cathode 708 into the electron injection layer 707. The injected hole and electron move respectively through the hole injection layer 704a and the hole transport layer 704b and the electron injection layer 707 and the electron transport layer 706 to reach the emission layer 705. The hole and the electron reached the emission layer 705 are recombined to emit light.

The layers from the hole injection layer 704a to the electron injection layer 707 in FIG. 7 are produced by a vapor deposition method, and the cathode 708 is produced by a sputtering film-forming method.

As described above, the organic EL display apparatus is manufactured by a process in which the sputtering film-forming method and the vapor-deposition method are mixed, and therefore, a film formation apparatus using the vacuum transfer apparatus of this invention is used, whereby the volume occupied by the apparatus can be reduced. Especially, since there are many film formation apparatuses of the organic EL display apparatus in which many film formation devices or processing devices are connected in line, this invention is very effective in the reduction of the volume occupied by the apparatus.

FIG. 8 is a perspective of an electron emission element display apparatus which is one of image display apparatuses particularly suitable for manufacture using the vacuum processing apparatus according to this invention.

Reference numerals 801, 802, 803, 804, 807, 810, 811, 812, 813, 814, and 815 respectively denote an electron source substrate, a row wiring, a column wiring, an electron emission element, a first getter, a second getter, a reinforcing plate, a frame, a glass substrate, a phosphor film, and a metal back. Dox 1 to Dox m represent column select terminals, and Doy 1 to Doy n represent row select terminals The glass substrate 813, the phosphor film 814, and the metal back 815 constitute a face plate.

In this display apparatus, the respective electron emission elements 804 are disposed at a position where the row wiring 802 and the column wiring 803 planarly intersect with each other. When a predetermined voltage is applied to the selected row wiring 802 and the selected column wiring 803, the electron is emitted from the electron emission element 804 located at the position where the row wiring 802 and the column wiring 803 planarly intersect with each other, and the electron is accelerated toward the face plate subjected to a high positive voltage. The electron collides with the metal back 815 to excite the phosphor film 814 in contact with the metal back 815, and, thus, to emit light. The first getter 807 is provided on the column wiring 803.

A space surrounded by the face plate, the frame 812, and the substrate 813 is maintained in vacuum. In order to maintain the space in the vacuum state during the life of the image display apparatus, a getter material is provided therein. The getter material includes an evaporation type getter and a non-evaporation type getter, and they are appropriately used. As an evaporation getter, there have been known elemental metals such as Ba, Li, Al, Hf, Nb, Ta, Th, Mo, and V or an alloy of these metals. On the other hand, as a non-evaporation getter, there have been known elemental metals such as Zr and Ti or an alloy of them.

In the example of FIG. 8, the row wiring 802 and the column wiring 803 formed of, for example, an Al alloy, copper, or Mo are normally film-formed by sputtering. On the other hand, the first getter 807 and the second getter 811 are often film-formed by vapor deposition. Thus, the method for manufacturing the electron emission element display apparatus has a process, in which the sputtering film-forming method and the vapor-deposition method are mixed, as in the organic EL display apparatus, and therefore, when the film formation apparatus using the vacuum transfer apparatus of this invention is used, the volume occupied by the apparatus can be reduced.

In the above description, this invention is applied to the electron emission element display apparatus and the organic EL display apparatus; however, this invention is generally effective in an apparatus, which includes such processing that in the substrate processing such as processing for forming an even film on a substrate with an increased size, a distance between the substrate and a target or a material source such as a vapor deposition source is required to be adjusted in each processing, or the processing method.

1.-15. (canceled)

16. A vacuum transfer apparatus comprising:
a vessel having an inside which can be evacuated into a vacuum;
first and second motion transfer means, positioned side by side in the vessel, for transferring a rotational driving force as a rotational motion, and can linearly move in their axis direction;
a base supported by the first and second motion transfer means so as to be allowed to linearly move in the axis direction;
a first arm having a first cylindrical part rotatably attached to the base and a first arm part attached at its one end to the first cylindrical part;
a second arm having a second cylindrical part rotatably attached to a second end of the first arm part and a second arm part attached at its one end to the second cylindrical part;
a first pulley fixed to an outer wall of the first cylindrical part;
a first rotation shaft located inside the first cylindrical part and having two pulleys;
a second pulley fixed to an outer wall of the second cylindrical part;
a belt bridging between the first motion transfer means and the first pulley fixed to the outer wall of the first cylindrical part;
a belt bridging between the second motion transfer means and one of the pulleys of the first rotation shaft; and
a belt bridging between the other pulley of the first rotation shaft and the second pulley fixed to the outer wall of the second cylindrical part.

17. The vacuum transfer apparatus according to claim 16, wherein the motion transfer means is a ball spline.

18. The vacuum transfer apparatus according to claim 16, further comprising vertical motion means for further supporting the base.

19. The vacuum transfer apparatus according to claim 18, wherein the vertical motion means is a ball screw.

20. The vacuum transfer apparatus according to claim 16, further comprising:
a second rotation shaft located inside the second cylindrical part and fixed at its one end to a third pulley fixed to the outer wall of the second cylindrical part;
a fourth pulley fixed to a second end of the second rotation shaft;
a hand rotatably attached to the second end of the second arm part through a third rotation shaft;
a fifth pulley fixed to the third rotation shaft; and
a belt bridging between the fourth pulley fixed to the second end of the second rotation shaft and the fifth pulley fixed to the third rotation shaft.

21. A vacuum processing apparatus comprising the vacuum transfer apparatus according to claim 16.

22. A method for manufacturing a display apparatus comprising a step using the vacuum transfer apparatus according to claim 16.

23. A method for manufacturing the display apparatus according to claim 22, wherein the display apparatus is an organic EL display apparatus.

24. A method for manufacturing the display apparatus according to claim 22, wherein the display apparatus is an electron emission element display apparatus.
